(19) United States
(12) Patent Application Publication
(10) Pub. No.: US 2011/0284048 A1
(43) Pub. Date: Nov. 24, 2011

(54) MULTI-LAYER SUPERLATTICE QUANTUM WELL THERMOELECTRIC MATERIAL AND MODULE

(75) Inventors: Frank HAASS, Erzhausen (DE); Norbert B. ELSNER, La Jolla, CA (US); Laverne Elsner, La Jolla, CA (US); Saeid GHAMATY, La Jolla, CA (US); Daniel KROMMENHOEK, San Diego, CA (US)

(73) Assignees: Hi - Z Technology, Inc., San Diego, CA (US); BASF SE, Ludwigshafen (DE)

(21) Appl. No.: 13/073,102

(22) Filed: Mar. 28, 2011

Related U.S. Application Data
(60) Provisional application No. 61/319,890, filed on Apr. 1, 2010.

(51) Int. Cl. H01L 35/12; H01L 35/34

(52) U.S. Cl. 136/236.1; 438/54; 136/201; 257/E21.04

(57) ABSTRACT

A multi-layer superlattice quantum well thermoelectric material comprising at least 10 alternating layers has a layer thickness of each less than 50 nm, the alternating layers being electrically conducting and barrier layers, wherein the layer structure shows no discernible interdiffusion leading to a break-up or dissolution of the layer boundaries upon heat treatment at a temperature in the range from 50 to 150° C. for a time of at least 100 hours and the concentration of doping materials in the conducting layers is 10¹⁸ to 10²³ cm⁻³ and in the barrier layers is 10¹³ to 10¹⁸ cm⁻³.

The present invention relates to thermoelectric materials for forming a multi-layer superlattice quantum well thermoelectric material, a thermoelectric module and a method for forming a multi-layer superlattice quantum well thermoelectric module.

Thermoelectric generators and Peltier arrangements as such have been known for some time. p- and n-doped semiconductors which are heated on one side and cooled on the other side transport electrical charges through an external circuit, and electrical work can be performed by a load in the circuit. The efficiency of conversion of heat to electrical energy achieved in this process is limited thermodynamically by the Carnot efficiency and by the materials thermoelectric properties. At a temperature of 1000 K on the hot side and 400 K on the cold side, according to the Carnot efficiency a conversion of (1000 K - 400 K)/1000 K =60% of the thermal energy input into electrical energy would be theoretically possible. However, only efficiencies of up to 6% have been achieved to date due to less efficient thermoelectric materials and parasitic losses within the real thermoelectric module.

On the other hand, when a direct current is applied to such an arrangement, heat is transported from one side to the other side. Such a Peltier arrangement works as a heat pump and is therefore suitable for cooling apparatus parts, vehicles or buildings. Heating via the Peltier principle is also more favorable than conventional heating, because more heat is always transported than corresponds to the energy equivalent supplied.

At present, thermoelectric generators are used in space probes for generating direct currents, for cathodic corrosion protection of pipelines, for energy supply to light buoys and radio buoys, for operating radios and television sets, and as auxiliary power units.

The advantage of thermoelectric generators is their extreme reliability. For instance, they work irrespective of atmospheric conditions such as atmospheric moisture; there is no fault-prone mass transfer, but rather only charge transfer. All kinds of heat sources can be used to power a thermoelectric generator. In a fuel driven device, it is possible to use any fuels from hydrogen through natural gas, gasoline, kerosene, diesel fuel up to biologically obtained fuels such as rapeseed oil methyl ester.

Thermoelectric energy conversion thus fits extremely flexibly into future requirements such as hydrogen economy or energy generation from renewable energies. Ideas in using superlattices to improve the thermoelectric figure of merit (ZT) through the enhancement of electronic conductivity and reduction of phononthermal conductivity have been discussed over recent years. Several research groups reported in recent years an enhanced ZT in various superlattices such as Bi₂Te₃/Sb₂Te₃ and Bi₂Te₂/Bi₂Se₃, and PbSeTe/PbTe quantum dot super lattices.

A general discussion of thin-film superlattice thermoelectric materials, devices and applications can be found in MRS bulletin, volume 31, March 2006, pages 211 to 217. The superlattices consist of alternating thin layers of different materials stacked periodically. The lattice mismatch and electronic potential differences at the interfaces, the resulting phonon and electron interface scattering and structure modifications can be exploited to reduce phonon heat conduction while maintaining or enhancing the electron transport.

PbSeTe-based quantum dot superlattice structures grown by molecular beam epitaxy have been investigated for applications in thermoelectrics. Respective results are discussed in Science, Vol. 297, 27 September 2002, pages 2229 to 2232.

Thermoelectric modules containing multi-layer superlattice quantum well thermoelectric materials in which the n-legs are comprised of very thin alternating layers of silicon and silicon carbide and p-legs are comprised of alternating layers of boron carbide comprising two different stoichiometric forms of boron carbide are disclosed in U.S. Pat. No. 7,342,170 and U.S. Pat. No. 6,828,579.

In the quantum well structures which consist of multilayers of materials with higher and lower electrical conductivity, the temperature gradient is applied parallel to the layers. In contrast to this, thin film thermoelectrics like Bi₂Te₃/Sb₂Te₃ or PbTe/PbSe multilayer systems have a temperature gradient applied only perpendicular to the layers.

Most thin film materials suffer from low thermal stability. At elevated temperatures as well as in a temperature gradient, layers of different materials start to mix, the multi-layer structure dissolves and the thermoelectric properties degrade. This happens especially in materials with high diffusion coefficients and in materials which form a stable layer structure but contain dopants or additives with high mobility. Degradation in the thermal gradient and the electrical field due to electromigration is the result, leading to poor figures of merit for the thermoelectric materials upon prolonged times of use.

The object underlying the present invention is to provide improved thermoelectric materials or thermoelectric module as well as methods for forming a multi-layer superlattice quantum well thermoelectric material which overcome the disadvantages of the prior art.

The object is achieved by a multi-layer superlattice quantum well thermoelectric material comprising at least 10 alternating layers having a layer thickness of each less than 50 nm, the alternating layers being electrically conducting and barrier layers, wherein the layer structure shows no discernible interdiffusion leading to a break-up or dissolution of the layer boundaries upon heat treatment at a temperature in the range from 50 to 150° C. above the anticipated hot side temperature for a time of at least 100 hours and the concentration of doping materials in the conducting layers is 10¹⁸ to 10²³ cm⁻³ or more than 10¹⁸ to 10²³ cm⁻³ and in the barrier layers is 10¹³ to 10¹⁸ cm⁻³ or 10¹³ to less than 10¹⁸ cm⁻³.

The object is furthermore achieved by a thermoelectric module comprised of:

A) a plurality of n-legs comprised each of at least 100 alternating layers having a layer thickness of each less than 50 nm; and

B) a plurality of p-legs comprised each of at least 100 alternating layers having a layer thickness of each less than 50 nm wherein said p-legs and said n-legs are electrically connected to produce said thermoelectric module, and the thermoelectric materials in the n- and p-legs contain a material as defined above.

The alternating layers are electrically conducting layers and insulating (barrier) layers.

The object is furthermore achieved by a method for forming a multi-layer superlattice quantum well thermoelectric module, comprising the step of combining thermoelectric materials as defined above for forming

A) a plurality of n-legs comprised each of at least 100 alternating layers having a layer thickness of each less than 50 nm; and

B) a plurality of p-legs, comprised each of at least 100 alternating layers having a layer thickness of each less than 50 nm wherein said p-legs and said n-legs are electrically connected to produce said thermoelectric module.

The present inventors have found that thermoelectric materials having a low diffusivity and a low concentration of structural defects preferably below 10¹⁹ cm⁻³in the conducting layers and below 10¹⁵cm⁻³ in the barrier layers are especially suited for forming a multi-layer superlattice quantum well thermoelectric material. The diffusivity can hardly be measured directly. Therefore, the diffusivity is determined indirectly by assessing the stability of the layer structure. If the diffusivity is high and a discernible interdiffusion occurs, the layer boundaries break-up or dissolve upon heat treatment.

According to the present invention, the layer structure shows no discernible interdiffusion leading to a break-up or dissolution of the layer boundaries upon heat treatment at a temperature in the range from 50 to 150° C. above the anticipated hot side temperature for a time of at least 100 hours.

Preferably, no discernible interdiffusion as stated above occurs at a heat treatment at a temperature in the range of preferably from 0 to 500° C., specifically -30 to 800° C. The time for the heat treatment is preferably at least 500 hours, especially at least 100 hours.

If no break-up or dissolution of the layer boundaries occurs in the above temperature and time ranges, the layer structure shows no discernible interdiffusion, so that the diffusivity is low.

The layers according to the present invention also have a low concentration of structural defects. The more defects in the lattice occur, the higher is the mobility (according to a hopping mechanism which needs free spaces). An appropriate range can be defined by the doting of the materials. According to the present invention a concentration of doting materials in the conducting layers is 10¹⁸ to 10²³ cm⁻³ and in the barrier layers 10¹³ to 10¹⁸ cm⁻³. Preferably, the concentration of doting materials in the conducting layers is 10¹⁹ to 10²² cm⁻³ and in the barrier layers around 10¹⁶ cm⁻³ (+1-20%). Preferably, the defect concentration is smaller than the doping concentration, thus preferably smaller than 10¹⁶ cm⁻³, more preferably smaller than 10¹⁵ cm⁻³ for the barrier layer and smaller than 10¹⁹ cm⁻³ and preferably smaller than 10¹⁸ cm⁻³ for the conducting layers.

Preferred materials show the low diffusivity in the quantum well forming materials.

The thermoelectric material preferably has a rigid crystal structure. Rigid crystal structures are supported by a more-dimensional structural network with covalent or partial-covalent bonds. Examples for materials having a rigid crystal structure are compounds with a diamond structure, such as Si or SiC.

Furthermore, preferred thermoelectric materials form clusters within the crystal structure. Borides like LaB₆ are examples for materials forming cluster within the structure.

Furthermore, preferred thermoelectric materials form a cage structure. Examples for thermoelectric materials forming a cage structure are clathrates. The thermoelectric material can be chosen from a wide range of thermoelectric materials. All materials can be employed as long as they fulfill the above requirements.

Preferably, the thermoelectric material is selected from the group consisting of borides, aluminides, carbides, silicides, germanides, stannides, nitrides, phosphides, arsenides, antimonides, oxides, sulfides, selenides, tellurides, metals and intermetallic alloys based on at least two metals selected from Sc, Y, Ti, Zr, Hf, V, Nb, Ta, Cr, Mo, W, Mn, Re, Fe, Ru, Os, Co, Rh, Ir, Ni, Pd, Pt, Cu, Ag, Au and mixtures thereof.

Preferred thermoelectric materials are carbides, silicides, borides, nitrides and oxides.

n-leg and p-leg materials are made by doping of the thermoelectric materials. The doping materials are known to the one skilled in the art. Some materials such as boron carbide may not need to be doped (intrinsic doping).

A background description of superlattice quantum well materials can be found in U.S. Pat. No. 7,342,170 in columns 1 and 2. The preferred layer geometry can be as disclosed in U.S. 2006/0208492, U.S. Pat. No. 6,828,579, U.S. Pat. No. 7,342,170, U.S. Pat. No. 6,060,656, U.S. Pat. No. 6,452,206.

According to one embodiment of the invention, the thermoelectric materials can be subjected to stress and strain in the material. This can be helpful to optimize the thermoelectric properties. An example for optimized thermoelectric properties by induced stress and strain is the system Si/SiGe. Stress and strain are difficult to quantify.

Therefore, it is more practical to define the preparation processes leading to stress and strain in the material. Preferred processes leading to stress and strain in the materials are the deposition at different temperatures, the deposition with different crystallographic orientations of the layers as well as the doting of the layers with defect inducing atoms which distort or twist the lattice due to impaired volume and valencies of the defect atoms.

An important feature of the layers can be its degree of crystallinity. In order to obtain good thermoelectric properties it is not necessary to have a single crystal of the material deposited on the layer, and can contain a certain disorder. According to the present invention, thus the layers need not be single crystalline, but can show a partial crystallinity of preferably at least 15%, more preferably at least 20%, specifically at least 25%.

In the thermoelectric modules of the present invention, the very thin alternating layers are preferably each less than 20 nm, more preferably less than 15 nm thick. They can, for example, have a layer thickness of about 10 nm.

More than 10 alternating layers can be formed on top of each other, preferably more than 100 alternating layers, especially more than 1000 alternating layers.

In the thermoelectric module, the plurality of n-legs comprised of alternating layers of insulating and non-insulating materials and the plurality of p-legs, said p-legs and said n-legs being electrically connected to produce said thermoelectric module, the directions of heat flow and electric current flow in said n-legs are parallel (in-plane) to said n-leg interfaces.

The layer sequence can be alternating or mirror-symmetrical. However, it is also possible to have other types of layer order, for example with three materials a sequence -A-B-C-B-A-B . . .

According to one embodiment of the present invention thicker buffer interlayers can be provided for which allow for a higher deposition quality and can relieve mechanical and thermal stress in the material. Such thicker interlayers can be at least 20 nm, more preferably at least 25 nm thick. They can be included preferably at least every 25 layers, more preferably at least every 50 layers. They are preferably composed of a non-conducting material which needs not be of the same material as one of the active conducting or non-conducting layers. However, due to the chemical compatibility it is preferred that these thicker interlayers contain the same materials as the normal layers and interlayers.

The thermoelectric modules according to the present invention are typically produced by depositing on a thin substrate a very large number of very thin alternating layers of the thermoelectric material; forming a stack of the film produced; producing a plurality of thermoelectric n-legs from said stacks; depositing on another thin substrate a very large number of very thin alternate layers of the thermoelectric material to form a thermoelectric film; forming a stack of said films; producing a plurality of thermoelectric p-legs from said stacks; and forming a thermoelectric module from said plurality of n-legs and said plurality of p-legs, said p-legs and said n-legs being electrically connected to produce said thermoelectric module.

The forming of the multi-layer superlattice quantum well thermoelectric material can be performed as described form example in US-A-2006/0208492, U.S. Pat. No. 7,342,170, U.S. Pat. No. 6,828,579, U.S. Pat. No. 6,060,656 or U.S. Pat. No. 6,452,206.

The deposition on the substrate material can be done by sputtering, MBE, CVD, PVD, evaporation techniques and other suitable techniques that may combine these processes. For example, film deposition can be performed using a Veeco magnetron sputtering unit, with 3-inch targets, and side by side-sputtering using 2 or 3 inch targets. Thereby, the thickness of each layer can be controlled to a high accuracy. The deposition rate is 10 nm/min but lower or higher rates may be suitable as well (1-50 nm/min, more preferably 2,5-20 nm/min).

The deposition can be on any useful substrate material. Suitable substrate materials are preferably chosen from Si, polymer films like Katon® and PTFE, porous Si, ceramic wavers like Al₂O₃, BaF₂, SiO₂MgO, glasses etc. Preferably, deposition is performed on a silicon waver. A crystalline top layer on an amorphous or less crystalline substrate, e.g. silicon on glass, can be helpful to grow non-amorphous layers. Non-amorphous layers are preferred due to their better electrical conductivity.

The heat conductivity of the substrate is preferably lower than 300 W/K m, more preferably smaller than 100 W/K m, especially lower than 10 W/K m. Ideally, the heat conductivity is as small as possible in order to minimize heat flowing through the substrate and not leading to a thermoelectric effect. Most preferably, thus the heat conductivity is lower than 1 W/K m.

According to one embodiment of the present invention the substrate layer is removed after completion of the deposition process.

The surface structure of the substrates needs not be crystalline. Preferably, it has a crystallographic match to the layers deposited onto the substrate. This crystallographic match leads to a good adhesion of the layers deposited on the substrate.

Generally, the substrate layer can be amorphous, partially crystalline or crystalline, even single crystalline. Layers of organic polymers need not be crystalline and nevertheless show a very good deposition of the thermoelectric materials. Inorganic amorphous substrate layers are less preferred.

A polymer film can for example be formed from polyimide substrate. An example of polyimide substrate films are Kapton® films.

For example, Kapton® film, thickness 25 μm, can be coated on both sides with a 0.1 micron thick layer of crystalline Si feeds take-up roll. Alternate layers of conducting n-type layers and insulating n-type layers can then be deposited on one side of the tape, and alternate layers of conducting p-type layers and insulating p-type layers are deposited on the other side, so that a n-leg is formed on one side and a p-leg is formed on the other side of the coated film. The film can be cut into individual pieces then and be used to built legs for thermoelectric modules.

Different legs can be separated by one layer of an insulating material film about 5 microns thick. Typically, a leg can have at least 100 layers of an average thickness of 10 nm.

The alternating film pieces can for example be 1 cm long and 2.65 cm wide, so that the completed element has the shape and size of 1 cm×2.65 cm×25 microns thick. A number of these elements, for example 20, can be joined together with silicon film to form a 20 couple thermoelectric set. The elements can be connected in series with a copper bond that may be made using a waver deposition process. The silicon insulating layers can be allowed to extend beyond the thermoelectric material where the legs are not to be connected so the copper deposit can be uniformly applied then lapped until the separating insulator layers are exposed.

Five of these twenty couple thermoelectric sets can then be joined together to form a 100 couple thermoelectric set. The five sets can be connected in parallel. Again, a number of these 100-element sets can be joined to form a higher couple thermoelectric module. For example five of these 100-element sets can be joined to form a 500-couple thermoelectric module. Such module can have dimensions of 2.65 cm×2.75 cm×1 cm. This module can be mounted with each of the two 7 cm² sides positioned tightly against a hot heat source at a cold heat sink. Again, the 100 element sets can be connected in parallel so that the voltage generated remains the same.

Apart from silicon and Kapton® many other organic materials such as mylar, polyethylene, polyamide, polyamide-imides and polyimide compounds can also be used as substrates. Other potential substrate materials are oxide films such as SiO₂, Al₂O₃ and TiO₂. Mica could also be used for substrates. The substrate preferably should be very thin and a very good thermal and electrical insulator with good thermal stability, strong and flexible. Substrates are, for example, discussed in U.S. 2006/0208492 in paragraphs [0049] to [0058]. This document also describes a preferred assembly of the thermoelectric module.

A quantum well power harvesting system is disclosed in U.S. 2006/0208492 on page 6.

1. A multi-layer superlattice quantum well thermoelectric material comprising at least 10 alternating layers having a layer thickness of each less than 50 rim, the alternating layers being electrically conducting and barrier layers, wherein the layer structure shows no discernible interdiffusion leading to a break-up or dissolution of the layer boundaries upon heat treatment at a temperature in the range from 50 to 150° C. for a time of at least 100 hours and the concentration of doping materials in the conducting layers is 10¹⁸ to 10²³ cm⁻³ and in the barrier layers is 10¹³ to 10¹⁸ cm⁻³.

2. The material as claimed in claim 1, wherein the thermoelectric material has a rigid crystal structure supported by a more-dimensional structural network with covalent or partial-covalent bonds, preferably a diamond structure.

3. The material as claimed in claim 1, wherein the thermoelectric material comprises at least 100 alternating layers.

4. The material as claimed in claim 1, wherein the thermoelectric material is selected from the group consisting of borides, aluminides, carbides, silicides, germanides, stannides, nitrides, phosphides, arsenides, antimonides, oxides, sulfides, selenides, tellurides, metals and intermetallic alloys based on at least two metals selected from Sc, Y, Ti, Zr, Hf, V, Nb, Ta, Cr, Mo, W, Mn, Re, Fe, Ru, Os, Co, Rh, Ir, Ni, Pd, Pt, Cu, Ag, Au and mixtures thereof.

5. The material as claimed in claim 1, wherein the thermoelectric material forms clusters within the crystal structure.

6. The material as claimed in claim 1, wherein the thermoelectric material forms a cage structure.

7. A thermoelectric module comprised of:
A) a plurality of n-legs comprised each of at least 100 alternating layers having a layer thickness of each less than 50 nm; and
B) a plurality of p-legs comprised each of at least 100 alternating layers having a layer thickness of each less than 50 nm
wherein said p-legs and said n-legs are electrically connected to produce said thermoelectric module, and the thermoelectric materials in the n- and p-legs contain a material as defined in claim 1.

8. The thermoelectric module as claimed in claim 7, wherein the thermoelectric module is designed for operation with parallel directions of heat flow and current flow both parallel to the layers in the n-legs.

9. The thermoelectric module as claimed in claim 7, wherein said alternating layers are deposited on a substrate.

10. A method for forming a multi-layer superlattice quantum well thermoelectric module, comprising the step of combining thermoelectric materials as defined in claim 1
A) a plurality of n-legs comprised each of at least 100 alternating layers having a layer thickness of each less than 50 nm; and
B) a plurality of p-legs, comprised each of at least 100 alternating layers having a layer thickness of each less than 50 nm
wherein said p-legs and said n-legs are electrically connected to produce said thermoelectric module.
